(19) United States
(12) Patent Application Publication
(10) Pub. No.: US 2025/0316227 A1
(43) Pub. Date: Oct. 9, 2025

(54) DISPLAY DEVICE AND METHOD OF DRIVING THE SAME

(71) Applicant: Samsung Display Co., LTD., Yongin-si (KR)

(72) Inventors: Se Hyun KWON, Yongin-si (KR); Nam Sik KO, Yongin-si (KR); Young Jin KO, Yongin-si (KR); Kwang Sub SHIN, Yongin-si (KR); Seong Keun HA, Yongin-si (KR)

(21) Appl. No.: 18/947,968

(22) Filed: Nov. 14, 2024

(30) Foreign Application Priority Data
Apr. 4, 2024 (KR) 10-2024-0045818

(51) Int. Cl. G09G 3/3233

(52) U.S. Cl. CPC G09G 3/3233; G09G 2300/0819; G09G 2300/0842; G09G 2300/0861; G09G 2310/0291; G09G 2310/0294; G09G 2310/061; G09G 2320/046; G09G 2360/144

(57) ABSTRACT

A display device includes a display panel in pixel rows are disposed; an emission driving circuit which supplies an emission control signal to pixels positioned in a first image display area, supplies the emission control signal to pixels positioned in a second image display area, and supplies the emission control signal of a turn-off level to pixel rows positioned in a black area between the first and second image display areas; a reset circuit which supplies a reset control signal to photo sensors positioned in the black area during a reset period; and a readout circuit which senses the photo sensors based on a cycle corresponding to a sensing period, where a length of a reset period during which the reset control signal of the turn-on level is inputted is equal to or greater than twice a length of the sensing period.

This application claims priority to Korean Patent Application No. 10-2024-0045818, filed on Apr. 4, 2024, and all the benefits accruing therefrom under 35 U.S.C. § 119, the content of which in its entirety is herein incorporated by reference.

### BACKGROUND

### (1) Field

Various embodiments of the disclosure relate to a display device and a method of driving the display device.

### (2) Description of the Related Art

With the development of information technology, the importance of a display device, which is a connection medium between a user and information, has been emphasized. Accordingly, various types of display device, such as a liquid crystal display device and an organic light-emitting display device, are widely used in various fields.

A display device may include a photo sensor. Based on the quantity of light that is incident on the photo sensor, the function of the display device may be controlled (e.g., the luminance of an image displayed on the display device may be adjusted), or a biometric authentication function (e.g., a fingerprint authentication function) may be provided.

### SUMMARY

In a display device including a photo sensor, it may be desired to accurately measure the quantity of external light (e.g., reflective light or the like) that is incident on the photo sensor. To this end, it may be desired to sense the photo sensor while reducing or mitigating influence of light (e.g., internal light) directly incident on the photo sensor from pixels adjacent to the photo sensor.

Various embodiments of the disclosure are directed to a display device capable of enhancing accuracy of sensing a photo sensor by reducing influence of internal light, and a method of driving the display device.

An embodiment of the disclosure provides a display device, including: a substrate on which a reset control line, a sensing line, and an emission control line are disposed; an emission driving circuit which supplies an emission control signal to the emission control line; a reset circuit which supplies a reset control signal to the reset control line; a pixel disposed on the substrate, where the pixel includes a pixel circuit connected to the emission control line, and a light emitting element which receives a current from the pixel circuit in response to the emission control signal of a turn-on level; a photo sensor disposed on the substrate, where the photo sensor includes a photo sensor driving circuit connected to the reset control line and the sensing line, and a light receiving element which receives a reset voltage in response to the reset control signal of a turn-on level; and a readout circuit which differentially amplifies and outputs voltages of the sensing line respectively sensed in response to a first sampling signal and a second sampling signal. In such an embodiment, a length of a reset period during which the reset control signal of the turn-on level is inputted is equal to or greater than twice a length of a sensing period which is a cycle on which the first sampling signal of a turn-on level is sequentially inputted.

In an embodiment, the pixel circuit may include: a driving transistor connected between a second node and a third node, and including a gate electrode connected to a first node; a first emission control transistor connected between the second node and a first power line, and including a gate electrode connected to the emission control line; and a second emission control transistor connected between the third node and the light emitting element, and including a gate electrode connected to the emission control line.

In an embodiment, the pixel circuit may further include a switching transistor connected between a data line and the second node, and including a gate electrode connected to a first scan line. In such an embodiment, the photo sensor driving circuit may include: a first sensor transistor connected to a fifth power line to which a power voltage is applied, and including a gate electrode connected to the light receiving element; a second sensor transistor connected between the first sensor transistor and the sensing line, and including a gate electrode connected to the first scan line; and a third sensor transistor connected between the light receiving element and a fourth power line to which the reset voltage is applied, and including a gate electrode connected to the reset control line.

In an embodiment, the pixel circuit may further include: a compensation transistor connected between the first node and the third node, and including a gate electrode connected to a fourth scan line; a first initialization transistor connected between the first node and a second power line, and including a gate electrode connected to a second scan line; a second initialization transistor connected between the light emitting element and a third power line, and including a gate electrode connected to a third scan line; and a storage capacitor including a first side electrode connected to the first node, and a second side electrode connected to the first power line.

In an embodiment, a length of a period in which the emission driving circuit supplies the emission control signal of the turn-on level to the emission control line may be greater than the length of the reset period.

In an embodiment, the readout circuit may include an integrator and a sample-and-hold circuit. In such an embodiment, the integrator may include: an operational amplifier including a first input terminal connected to the sensing line, and a second input terminal to which a constant voltage is applied; a feedback capacitor connected between the first input terminal of the operational amplifier and an output terminal of the operational amplifier; and a first switching element connected between the first input terminal of the operational amplifier and the output terminal of the operational amplifier. In such an embodiment, the sample-and-hold circuit may include: a second switching element which switches electrical connection between the output terminal of the operational amplifier and a first sampling capacitor in response to the second sampling signal; a third switching element which switches electrical connection between the output terminal of the operational amplifier and a second sampling capacitor in response to the first sampling signal; and a differential amplifier including a first input terminal which receives a voltage corresponding to a voltage stored in the first sampling capacitor, and a second input terminal which receives a voltage corresponding to a voltage stored in the second sampling capacitor.

In an embodiment, the first switching element may electrically connect the first input terminal of the operational amplifier to the output terminal of the operational amplifier in response to an integrator reset signal. In such an embodiment, the integrator reset signal of a turn-on level, the second sampling signal of a turn-on level, and the first sampling signal of a turn-on level may be sequentially inputted.

In an embodiment, the readout circuit may further include: a fourth switching element connected to the output terminal of the operational amplifier; and an analog-to-digital converter which converts a sensing voltage inputted thereto through the fourth switching element to a digital value and output the digital value.

In an embodiment, the length of the sensing period may be equal to or greater than two horizontal periods.

In an embodiment, the pixel and the photo sensor may be positioned in an area on the substrate. In such an embodiment, the reset control signal may be inputted within a period during which the emission control signal of a turn-off level is supplied to the pixel.

In an embodiment, a length of a period in which the first sampling signal is at a turn-on level may be greater than a length of a period during which the second sampling signal is at a turn-on level.

An embodiment of the disclosure provides a display device, including: a display panel in which a plurality of pixel rows are disposed; an emission driving circuit which supplies an emission control signal of a turn-on level to pixels positioned in a first image display area, supply an emission control signal of a turn-on level to pixels positioned in a second image display area, and supply an emission control signal of a turn-off level to pixel rows positioned in a black area located between the first image display area and the second image display area; a reset circuit which supplies a reset control signal of a turn-on level to a plurality of photo sensors positioned in the black area during a reset period; and a readout circuit which senses the plurality of photo sensors based on a cycle corresponding to a sensing period. In such an embodiment, a length of a reset period during which the reset control signal of the turn-on level is inputted is equal to or greater than twice a length of the sensing period.

In an embodiment, at least one of the plurality of pixel rows may include a pixel and the photo sensor. In such an embodiment, the pixel may include: a pixel circuit which receives the emission control signal; and a light emitting element which receives current from the pixel circuit in response to the emission control signal of the turn-on level. In such an embodiment, the photo sensor may include: a photo sensor driving circuit connected to a sensing line, where the photo sensor may receive the reset control signal; and a photo sensor which receives a reset voltage in response to the reset control signal of the turn-on level.

In an embodiment, the readout circuit may be connected to the sensing line.

In an embodiment, the readout circuit may include an integrator and a sample-and-hold circuit. In such an embodiment, the integrator may include: an operational amplifier including a first input terminal connected to the sensing line, and a second input terminal to which a constant voltage is applied; a feedback capacitor connected between the first input terminal of the operational amplifier and an output terminal of the operational amplifier; and a first switching element connected between the first input terminal of the operational amplifier and the output terminal of the operational amplifier. In such an embodiment, the sample-and-hold circuit may include: a second switching element which switches electrical connection between the output terminal of the operational amplifier and a first sampling capacitor in response to a second sampling signal; a third switching element which switches electrical connection between the output terminal of the operational amplifier and a second sampling capacitor in response to a first sampling signal; and a differential amplifier including a first input terminal which receives a voltage corresponding to a voltage stored in the first sampling capacitor, and a second input terminal which receives a voltage corresponding to a voltage stored in the second sampling capacitor.

In an embodiment, the sensing period may correspond to a period between timings at which the first sampling signal of a turn-on level is sequentially inputted.

In an embodiment, the length of the sensing period may be equal to or greater than two horizontal periods.

An embodiment of the disclosure provides a method of driving a display device, including: supplying an emission control signal of a turn-on level to a plurality of pixel rows positioned in a first image display area of a display panel; supplying the emission control signal of the turn-on level to a plurality of pixel rows positioned in a second image display area of the display panel; supplying the emission control signal of a turn-off level to a plurality of pixel rows positioned in a black area between the first image display area and the second image display area of the display panel; supplying a reset control signal of a turn-on level to a plurality of photo sensors positioned in the black area; and sensing the plurality of photo sensors based on a cycle corresponding to a sensing period. In such an embodiment, a length of a reset period during which the reset control signal of the turn-on level is inputted is equal to or greater than twice a length of the sensing period.

In an embodiment, the length of the sensing period may be equal to or greater than two horizontal periods.

In an embodiment, the supplying the reset control signal of the turn-on level to the plurality of photo sensors may include applying a reset voltage to a light receiving element of each of the plurality of photo sensors.

### BRIEF DESCRIPTION OF THE DRAWINGS

FIG. 1 is a schematic system diagram of an electronic device in accordance with embodiments of the disclosure.

FIG. 2A is a diagram illustrating a display device and a processor in accordance with embodiments of the disclosure.

FIG. 2B is a diagram illustrating a display device and a processor in accordance with embodiments of the disclosure.

FIG. 3 is a system diagram of the display device in accordance with embodiments of the disclosure.

FIG. 4 is a diagram illustrating a pixel row in accordance with embodiments of the disclosure.

FIG. 5 is a diagram illustrating a pixel and a photo sensor which are positioned in a first area in accordance with embodiments of the disclosure.

FIG. 6 is a diagram illustrating an equivalent circuit of the pixel and an equivalent circuit of the photo sensor in accordance with embodiments of the disclosure.

FIG. 7 is a diagram illustrating image display areas and a black area at a first timing in a display panel in accordance with embodiments of the disclosure.

FIG. 8 is a diagram illustrating the image display areas and the black area at a second timing in the display panel in accordance with embodiments of the disclosure.

FIG. 9 is a timing diagram illustrating an emission control signal and a reset control signal in accordance with embodiments of the disclosure.

FIG. 10 illustrates an equivalent circuit diagram of a readout circuit in accordance with embodiments of the disclosure.

FIG. 11 is a timing diagram of a first scan signal, an integrator reset signal, and sampling signals in accordance with embodiments of the disclosure.

FIG. 12 is a timing diagram illustrating lengths of a reset period and a sensing period in accordance with embodiments of the disclosure.

FIG. 13 is a perspective diagram illustrating an application example of the electronic device of FIG. 1.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the drawings, portions which are not related to the disclosure will be omitted in order to explain the disclosure more clearly. Reference should be made to the drawings, in which similar reference numerals are used throughout the different drawings to designate similar components. Therefore, the aforementioned reference numerals may be used in other drawings.

For reference, the size of each component and the thicknesses of lines illustrating the component are arbitrarily represented for the sake of explanation, and the disclosure is not limited to what is illustrated in the drawings. In the drawings, the thicknesses of the components may be exaggerated to clearly depict multiple layers and areas.

Furthermore, the expression “being the same” may mean “being substantially the same”. In other words, the expression “being the same” may include a range that can be tolerated by those skilled in the art. The other expressions may also be expressions from which “substantially” has been omitted.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element. In the disclosure, the singular forms are intended to include the plural forms as well, unless the context clearly indicates otherwise.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

The terms “under”, “below”, “above”, “upper”, and the like are used herein for explaining relationship between one or more components illustrated in the drawings. These terms may be relative terms describing the positions of components in the drawings, but the positions of components are not limited thereto.

Unless otherwise defined, all terms (including technical and scientific terms) used herein have the same meaning as commonly understood by one of ordinary skill in the art to which this invention belongs. Furthermore, terms as defined in a commonly used dictionary should be construed as having the same meaning as in an associated technical context, and unless defined apparently in the description, the terms are not ideally or excessively construed as having formal meaning.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the disclosure will hereinafter be described in detail with reference to the accompanying drawings.

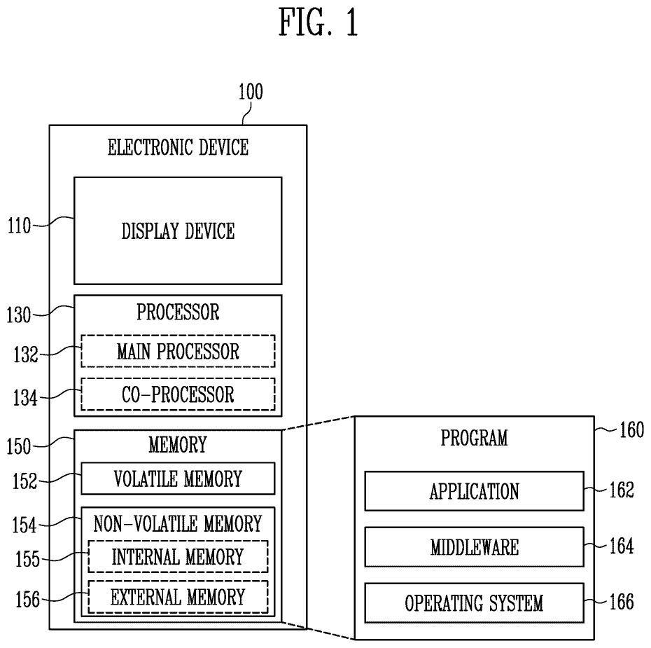

FIG. 1 is a schematic system diagram illustrating an electronic device 100 in accordance with embodiments of the disclosure.

Referring to FIG. 1, the electronic device 100 in accordance with embodiments of the disclosure may include a display device 110, a processor 130, and a memory 150.

The display device 110 may provide visual information to the outside (e.g., a user) of the electronic device 100. The display device 110 may include, for example, a display panel, a driving circuit, or the like. The display device 110 in accordance with embodiments of the disclosure may include a touch sensor set (or configured) to sense a touch, a pressure sensor set to measure the magnitude of force generated by the touch, and/or the like.

The processor 130 may execute, for example, software (e.g., a program 160) to control at least one other component (e.g., a hardware or software component) of the electronic device 100 connected to the processor 130, and may perform various data processing or computing operations. In accordance with embodiments of the disclosure, as at least a portion of the data processing or computing operation, the processor 130 may store data received from other components (e.g., the display device 110) in a volatile memory 152, process a command or data stored in the volatile memory 152, and store result data in a non-volatile memory 154. In accordance with embodiments of the disclosure, the processor 130 may include a main processor 132 (e.g., a central processing unit or an application processor) or an auxiliary processor 134 (or a co-processor 134) {e.g., a graphic processing unit (GPU), a neural processing unit (NPU), and an image signal processor, a sensor hub processor, a communication processor, or the like} capable of being operated independently or along with the main processor 132. For example, in the case where the electronic device 100 includes the main processor 132 and the auxiliary processor 134, the auxiliary processor 134 may be operated with low power consumption compared to that of the main processor 132, or may be set to be specialized for a preset function. The auxiliary processor 134 may be implemented as a separate component from the main processor 132 or part of the main processor 132.

The auxiliary processor 134 may control a function or at least some states pertaining to at least one component (e.g., the display device 110) among components of the electronic device 100, for example, in lieu of the main processor 132 while the main processor 132 is in an inactive state (e.g., a sleeping state), or along with the main processor 132 while the main processor 132 is in an active state (e.g., an application executing state). In accordance with embodiments of the disclosure, the auxiliary processor 134 (e.g., the image signal processor or the communication processor) may be implemented as a part of another component (e.g., a camera module (not illustrated), a communication module (not illustrated), or the like), which is functionally related thereto. In accordance with embodiments of the disclosure, the auxiliary processor 134 (e.g., the neural processing unit) may include a hardware structure specialized for processing an artificial intelligence (AI) model. The AI model may be generated by machine learning.

The memory 150 may store various data to be used by at least one component (e.g., the processor 130) of the electronic device 100. The data may include, e.g., input data or output data for software (e.g., the program 160) and a command pertaining thereto. The memory 150 may include the volatile memory 152 or the non-volatile memory 154. The non-volatile memory 154 may include an internal memory 155. The non-volatile memory 154 may further include an external memory 156.

The program 160 may be stored as software in the memory 150, and may include, for example, an application 162, middleware 164, and an operating system 166.

The electronic device 100 in accordance with embodiments of the disclosure may be referred to as a mobile station, mobile equipment (ME), user equipment (UE), a user terminal (UT), a subscriber station (SS), a wireless device, a handheld device, an access terminal (AT), or the like. The electronic device 100 in accordance with embodiments of the disclosure may be a device such as a cellular phone, a personal digital assistant (PDA), a smart phone, a wireless MODEM, or a notebook computer, having a communication function.

The electronic device 100 in accordance with embodiments of the disclosure may include a power management module (not illustrated) configured to manage power to be supplied to the electronic device 100. The power management module may be implemented, for example, as at least a part of a power management integrated circuit (PMIC).

At least some of the components of the electronic device 100 in accordance with embodiments of the disclosure may be connected to each other and exchange signals (e.g., a command or data) with each other through a communication scheme (e.g., a bus, general purpose input and output (GPIO)) between peripheral devices, a mobile industry processor interface (MIPI), or the like.

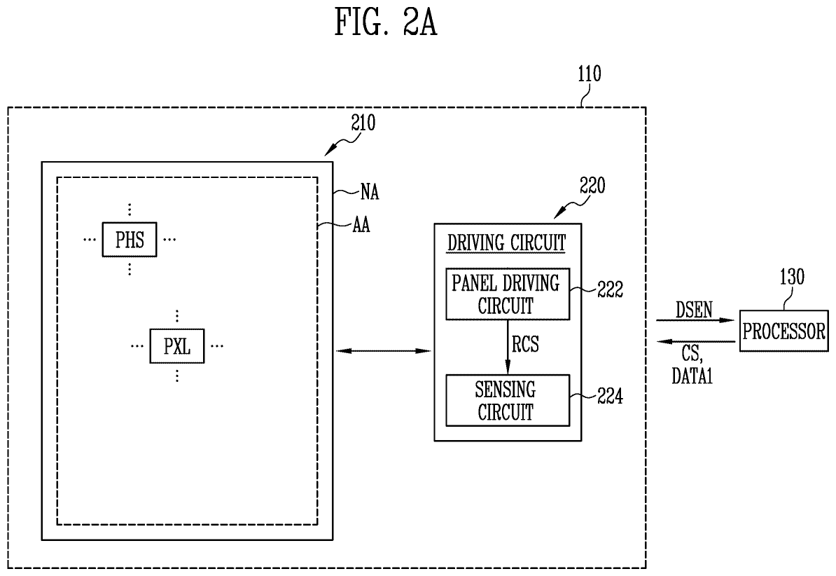

FIG. 2A is a diagram illustrating the display device 110 and the processor 130 in accordance with embodiments of the disclosure.

Referring to FIG. 2A, the display device 110 in accordance with embodiments of the disclosure may include a display panel 210 and a driving circuit 220.

The display panel 210 may include a display area AA in which a pixel PXL is disposed, and a non-display area NA disposed in a peripheral area (e.g., an edge area) of the display area AA. One or more pixels (or referred also to as pixels) PXL may be disposed in the display area AA. One or more photo sensors PHS may be disposed in the display area AA.

The pixel PXL may be configured to display an image on the display device 110. The pixel PXL may emit light at luminance corresponding to a voltage (e.g., a data voltage) inputted thereto from the driving circuit 220.

The photo sensor PHS may be configured to detect a light receiving amount or an amount of light incident thereto. The photo sensor PHS may include a light receiving element. Depending on the intensity of light incident on the photo sensor PHS, the magnitude of current flowing through the photo sensor PHS (or flowing through the light receiving element) may be changed. Light to be incident on the photo sensor PHS may include reflective light. Here, the reflective light may refer to light that is emitted from the display device 110 and then reflected by an external object (e.g., a surface of a person's finger). For example, depending on the intensity of reflective light (or the quantity of reflective light), the magnitude of current flowing through the photo sensor PHS may be changed.

One or more pins (e.g., a pad) may be disposed in the non-display area NA. The display panel 210 and at least some components of the driving circuit 220 may be electrically connected to each other through the pins.

The driving circuit 220 may include a panel driving circuit 222 and a sensing circuit 224.

The panel driving circuit 222 may generate a signal for supplying a voltage to the display panel 210. In an embodiment, for example, the panel driving circuit 222 may include a data driving circuit configured to output a data voltage, a scan driving circuit configured to supply a scan signal, an emission driving circuit configured to supply an emission control signal, or the like. The panel driving circuit 222 may include, for example, a timing controller configured to control operation timings of the data driving circuit, the scan driving circuit, and the emission driving circuit.

The sensing circuit 224 may be configured to control sensing operation of the photo sensor PHS disposed on the display panel 210.

The panel driving circuit 222 may output a readout circuit control signal RCS. The sensing circuit 224 may receive the readout circuit control signal RCS from the panel driving circuit 222. A timing (or a length of a period) at which the sensing circuit 224 senses the photo sensor PHS may be controlled by the readout circuit control signal RCS.

The sensing circuit 224 may convert a value obtained by sensing the photo sensor PHS to a corresponding digital value. In an embodiment, the sensing circuit 224 may include an analog-to-digital converter configured to convert an analog voltage vale to a corresponding digital value DSEN. The sensing circuit 224 may output the converted digital value DSEN. The processor 130 may receive the digital value DSEN.

The processor 130 may output a control signal CS for controlling an operation timing of the driving circuit 220. The processor 130 may output first image data DATA1 to the driving circuit 220.

The driving circuit 220 may receive the control signal CS and the first image data DATA1 and display an image through the pixels PXL of the display panel 210, or may detect a light receiving amount through the photo sensor PHS of the display panel 210.

The processor 130 in accordance with embodiments of the disclosure may generate an image based on the inputted digital value DSEN.

FIG. 2B is another diagram illustrating the display device 110 and the processor 130 in accordance with embodiments of the disclosure.

Referring to FIG. 2B, the display panel 210 in accordance with embodiments of the disclosure include a first display area AA1 and a second display area AA2.

Pixels PXL may be disposed in the first display area AA1. Pixels PXL and photo sensors PHS may be disposed in the second display area AA2. In an embodiment, no photo sensor PHS may be disposed in the first display area AA1.

In an embodiment, a surface (or planar) area of the first display area AA1 may be greater than a surface (or planar) area of the second display area AA2.

In an embodiment, the second display area AA2 may be enclosed by the first display area AA1. However, embodiments of the disclosure are not limited to the foregoing example.

In an embodiment, the second display area AA2 may be positioned or defined to be biased or closer to one side (e.g., a lower side) in the display panel 210. However, embodiments of the disclosure are not limited to the foregoing example. In another embodiment, the second display area AA2 may be positioned or defined on an upper, left, or right side of the display panel 210, or may be positioned or defined in a central area of the display panel 210.

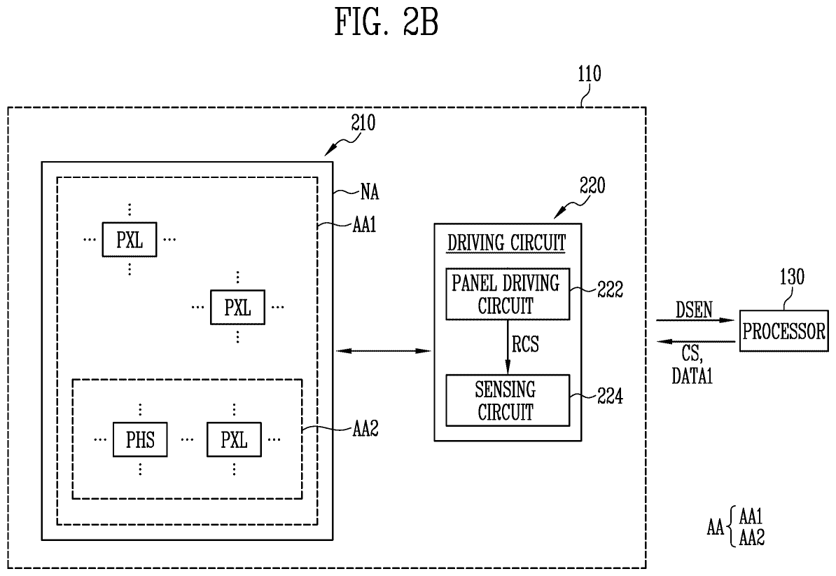

FIG. 3 is a system block diagram illustrating the display device in accordance with embodiments of the disclosure.

Referring to FIG. 3, the display device 110 (refer to FIG. 1) in accordance with embodiments of the disclosure may include a display panel 210, a data driving circuit 310, a scan driving circuit 320, an emission driving circuit 330, a timing controller 340, a readout circuit 350, a reset circuit 360, or the like.

The panel driving circuit 222 may include a data driving circuit 310, a scan driving circuit 320, an emission driving circuit 330, a timing controller 340, or the like. The sensing circuit 224 may include a readout circuit 350, a reset circuit 360, or the like.

The display panel 210 may include a substrate SUB. One or more pixels PXL may be disposed on the substrate SUB. One or more photo sensors PHS may be disposed on the substrate SUB. One or more power voltages may be supplied to the display panel 210. The power voltages may refer to voltages which are inputted in common to a plurality of pixels PXL, or voltages which are inputted in common to a plurality of photo sensors PHS.

The power voltages may include a first power voltage VDD, a second power voltage VSS, a third power voltage VRST, a fourth power voltage VCOM, or the like. The power voltages may be inputted in common to a plurality of pixels PXL and/or a plurality of photo sensors PHS, and may be referred to as common voltages. In an embodiment, for example, the power voltages may be generated from a power managing module.

A plurality of data lines DL1 to DLn (where n is an integer of 2 or greater) may be disposed on the display panel 210. The plurality of data lines DL1 to DLn may be disposed to extend in a second direction DR2 on the display panel 210. In an embodiment, the second direction DR2 may be, for example, a direction in which an upper side and a lower side of the display panel 210 are connected to each other (e.g., a column direction). In another embodiment, for example, the second direction DR2 may be a direction in which a left side and a right side of the display panel 210 are connected to each other (e.g., a row direction). Hereinafter, for convenience of description, the second direction DR2 will be defined as the direction in which the upper side and the lower side of the display panel 210 are connected to each other. However, the embodiments of the disclosure are not limited to the aforementioned example.

A plurality of scan lines SCL1 to SCLm (where m is an integer of 2 or greater) may be disposed on the display panel 210. The plurality of scan lines SL1 to SLm may be disposed to extend in a first direction DR1 on the display panel 210. In an embodiment, the first direction DR1 may be, for example, a direction in which the left side and the right side of the display panel 210 are connected to each other. In another embodiment, for example, the first direction DR1 may be a direction in which the upper side and the lower side of the display panel 210 are connected to each other. In an embodiment, for example, the first direction DR1 may be a direction perpendicular to the second direction DR2. In the following description, for convenience of description, the first direction DR1 will be defined as the direction in which the left side and the right side of the display panel 210 are connected to each other, but embodiments of the disclosure are not limited thereto.

The words “disposed to extend in the second direction DR2” may mean that lines are disposed to generally extend in a direction in which the upper side and the lower side are connected to each other, and may not exclude that the lines partially extend in other directions different from the second direction DR2. For example, in embodiments of the disclosure, at least one data line of the plurality of data lines DL1 to DLn may be designed to partially detour and extend in a direction different from the second direction DR2 and thus avoid a specific area (e.g., a high transmittance area). The words “disposed to extend in the first direction DR1” may also be used in the same sense as the words “disposed to extend in the second direction DR2”.

A plurality of emission control lines EML1 to EMLm may be disposed on the display panel 210. The plurality of emission control lines EML1 to EMLm may be disposed to extend in the first direction DR1 on the display panel 210.

A plurality of sensing lines RX1 to RXo (where o is an integer of 2 or greater) may be disposed on the display panel 210. The plurality of sensing lines RX1 to RXo may be disposed to extend in the second direction DR2 on the display panel 210.

One or more reset control lines RSTL may be disposed on the display panel 210. A reset control signal RST may be supplied to the reset control line RSTL.

Each pixel PXL may be electrically connected to a corresponding one of the plurality of data lines DL1 to DLn. Each pixel PXL may be electrically connected to a corresponding one of the plurality of scan lines SCL1 to SCLm. Each pixel PXL may be electrically connected to a corresponding one of the plurality of emission lines EML1 to EMLm.

Each photo sensor PHS may be electrically connected to a corresponding one of the plurality of sensing lines RX1 to RXo. The photo sensor PHS may be electrically connected to the reset control line RSTL. In an embodiment, the photo sensor PHS may be electrically connected to at least one (e.g., a corresponding one) of the plurality of scan lines SCL1 to SCLm.

In an embodiment, the plurality of pixels PXL may be disposed in the form of a matrix in the display panel 210. In the form of a matrix, the plurality of pixels PXL may be disposed in an RGBG-type array, or may be disposed to have a PENTILE™ structure having a rhombus shape.

The data driving circuit 310 may be configured to supply (or apply, or output) data voltages to the plurality of data lines DL1 to DLn. The data driving circuit 310 may receive a data driving circuit control signal DCS and second image data DATA2, and supply data voltages (or data signals) corresponding to the image data to the plurality of data liens DL1 to DLn at timings determined based on the data driving circuit control signal DCS.

The scan driving circuit 320 may be configured to supply scan signals to the plurality of scan lines SCL1 to SCLm. In an embodiment, the scan driving circuit 320 may be configured to sequentially supply scan signals (e.g., scan signals with a turn-on level) to the plurality of scan lines SCL1 to SCLm, but the embodiments of the disclosure are not limited thereto. The scan driving circuit 320 may receive a scan driving circuit control signal SCS, and supply scan signals to the plurality of scan lines SL1 to SLm at timings determined based on the scan driving circuit control signal SCS.

The emission driving circuit 330 may be configured to supply emission control signals to the plurality of emission control lines EML1 to EMLm. In an embodiment, the emission driving circuit 330 may be configured to sequentially supply emission control signals (e.g., emission control signals with a turn-on level) to the plurality of emission control lines EML1 to EMLm. However, the embodiments of the disclosure are not limited to the aforementioned example. The emission driving circuit 330 may receive an emission driving circuit control signal ECS, and supply emission control signals to the plurality of emission control lines EML1 to EMLm at timings determined based on the emission driving circuit control signal ECS.

The timing controller 340 may receive the control signal CS and the first image data DATA1, and may generate and output the data driving circuit control signal DCS, the scan driving circuit control signal SCS, the emission driving circuit control signal ECS, the second image data DATA2, the readout circuit control signal RCS, or the like, based on the inputted control signal CS and first image data DATA1.

The readout circuit 350 may be electrically connected to a plurality of sensing lines RX1 to RXo. The readout circuit 350 may be configured to sense (or to receive sensing result of) a plurality of photo sensors PHS through the plurality of sensing lines RX1 to RXo. For example, depending on the design of the readout circuit 350, the readout circuit 350 may integrate current flowing through at least one of the plurality of sensing lines RX1 to RXo (i.e., through a current sensing scheme), or may sense a voltage of at least one of the plurality of sensing lines RX1 to RXo (i.e., through a voltage sensing scheme). The readout circuit 350 may include a multiplexer configured to integrate the current (or to sense the voltage) of at least one of the plurality of sensing lines RX1 to RXo. Although hereinafter for convenience of description, a case where the readout circuit 350 employs the current sensing scheme will be described by way of example, the embodiments of he disclosure is not limited thereto.

The readout circuit 350 may include an analog-to-digital converter (ADC) 352 configured to convert a sensed analog voltage to a digital value DSEN.

The reset circuit 360 may be configured to supply reset control signals RST to the plurality of photo sensors PHS. When the reset control signal RST is supplied to the photo sensor PHS, electrical connection between the photo sensor PHS and the sensing line (e.g., a k-th sensing line RXk) may be disconnected. A timing at which the reset circuit 360 outputs the reset control signal RST may be controlled by the timing controller 340.

One or more circuits that constitute the panel driving circuit 222 may be disposed in the display device 110 (refer to FIG. 1) in the form of an integrated circuit (IC). In an embodiment, for example, the data driving circuit 310 may include a source driver integrated circuit (SDIC).

The one or more circuits that constitute the panel driving circuit 222 may be formed together during a process of forming the display panel 210. In an embodiment, for example, the scan driving circuit 320 may be formed together during a process of forming one or more circuit elements (e.g., a transistor, a capacitor, or the like) included in the pixel PXL and/or the photo sensor PHS.

The data driving circuit 310, the scan driving circuit 320, the emission driving circuit 330, and the timing controller 340 are merely classified based on the function in the panel driving circuit 222, and two or more components may be components which are functionally distinguished from each other in one integrated circuit. For example, the data driving circuit 310 and the timing controller 340 may be implemented as a single integrated circuit, and may be functionally distinguished from each other in the integrated circuit. For example, the scan driving circuit 320 and the emission driving circuit 330 may be implemented as a single integrated circuit, and may be functionally distinguished from each other in the integrated circuit.

The panel driving circuit 222 and the sensing circuit 224 are merely classified based on the function in the display device 110 (refer to FIG. 1). In an embodiment, the panel driving circuit 222 and the sensing circuit 224 may be respectively implemented in different integrated circuits, but in some cases, the panel driving circuit 222 and the sensing circuit 224 may be functionally distinguished from each other in a single integrated circuit.

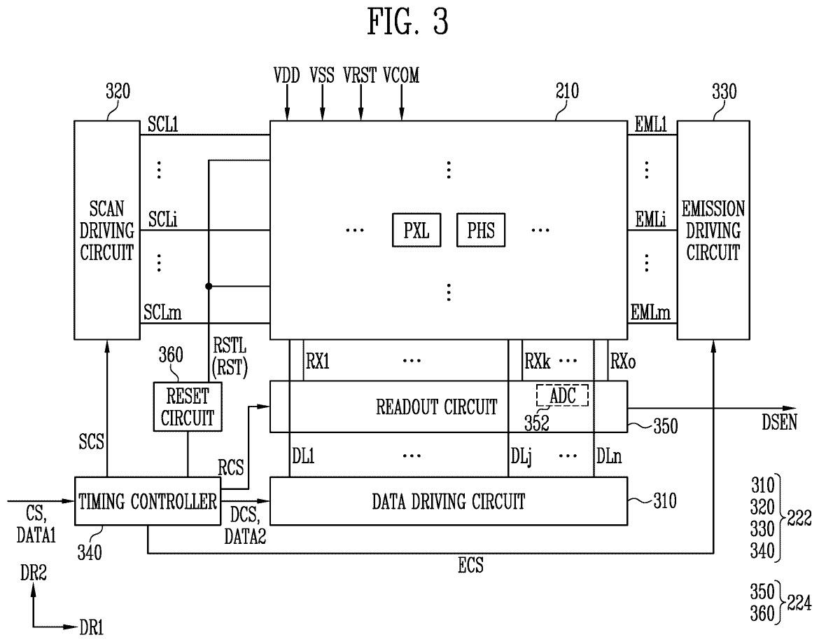

FIG. 4 is a diagram illustrating a pixel row in accordance with embodiments of the disclosure.

Referring to FIG. 4, a pixel row may be defined in embodiments of the disclosure. Each of a plurality of pixel rows PXR[1] to PXR[m] may include two or more pixels. Each of the plurality of pixel rows PXR[1] to PXR[m] may extend in the first direction DR1. The plurality of pixel rows PXR[1] to PXR[m] may be positioned adjacent to each other in the second direction DR2.

At least one of the plurality of pixel rows PXR[1] to PXR[m] may include a photo sensor PHS (refer to FIGS. 2A and 2B). In an embodiment, each of the plurality of pixel rows PXR[1] to PXR[m] may include a photo sensor PHS. In an embodiment, some of the pixel rows PXR[1] to PXR[m] may include a photo sensor, and the remaining of the pixel rows PXR[1] to PXR[m] may not include a photo sensor.

Two or more pixels included in each pixel row, e.g., an i-th pixel row PXR[i] (where i is an integer equal to or greater than 1 and equal to or less than m), may be electrically connected to one scan line.

The pixels PXL (refer to FIG. 3) and the photo sensors PHS (refer to FIG. 3) that are included in one pixel row (e.g., the i-th pixel row PXR[i]) may be electrically connected to one scan line.

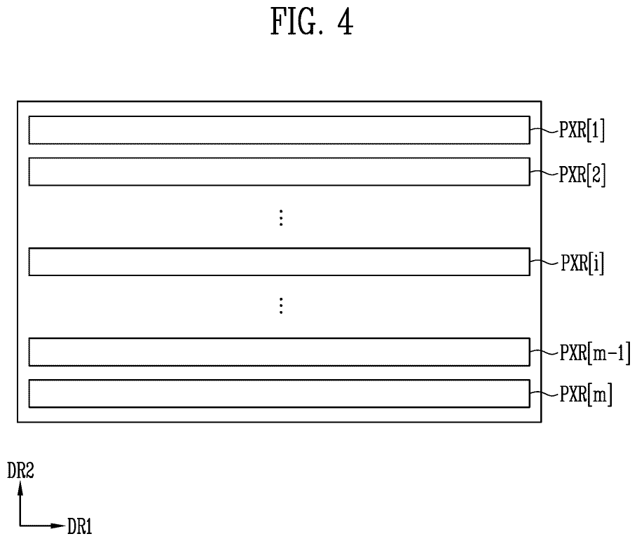

FIG. 5 is a diagram illustrating a pixel PXL and a photo sensor PHS which are located in the first area AREA1 in accordance with embodiments of the disclosure.

The first area AREA1 may include an area in which an i-th scan line SCLi is disposed, an i-th emission line EMLi is disposed, a j-th data line DLj (where j is an integer equal to or greater than 1 and equal to or less than n) is disposed, and a k-th sensing line RXk is disposed. The first area AREA1 may include an area in which a reset control line RSTL is disposed.

Referring to FIG. 5, the pixel PXL located in the first area AREA1 may be electrically connected to the i-th scan line SCLi, the i-th emission control line EMLi, and the j-th data line DLj. The photo sensor PHS located in the first area AREA1 may be electrically connected to the i-th scan line SCLi, the k-th sensing line RXk, and the reset control line RSTL.

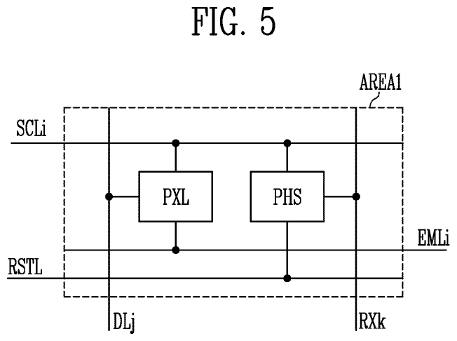

FIG. 6 is a diagram illustrating an equivalent circuit of the pixel PXL and an equivalent circuit of the photo sensor PHS in accordance with embodiments of the disclosure.

Referring to FIG. 6, in an embodiment, the pixel PXL may include a pixel driving circuit PXC and a light emitting element LD. In such an embodiment, the photo sensor PHS may include a photo sensor driving circuit PSC and a light receiving element LRD.

The pixel driving circuit PXC may be configured to adjust the magnitude of current flowing through the light emitting element LD. The pixel driving circuit PXC may include two or more transistors and one or more capacitors. Although the pixel driving circuit PXC may be implemented in various ways according to the design of those of the art, an embodiment having a structure (referred also to as a 7T1C structure) in which the pixel driving circuit PXC includes seven transistors and one capacitor will be described by way of example with reference to an equivalent circuit illustrated in FIG. 6.

Referring to FIG. 6, the pixel driving circuit PXC may include first to seventh transistors TR1 to TR7 and one storage capacitor Cst.

The pixel driving circuit PXC may be connected to an i-th scan line SCLi (hereinafter, referred also to as a scan line SCLi), an i-th emission control line EMLi (hereinafter, referred also to as an emission control line EMLi), and a j-th data line DLj (hereinafter, referred also to as a data line DLj).

The scan line SCLi may include first to fourth scan lines S1i, S2i, S3i, and S4i.

The first pixel transistor TR1 may be configured to adjust the magnitude of current flowing between a second node N2 and a third node N3 in response to a voltage of a first node N1. The first node N1 may be electrically connected to a gate electrode of the first pixel transistor TR1. The second node N2 may be electrically connected to one electrode of the first pixel transistor TR1 (e.g., one of a source electrode or a drain electrode). The third node N3 may be electrically connected to the other electrode of the first pixel transistor TR1 (e.g., the other one of the source electrode or the drain electrode). Depending on the magnitude of a voltage to be applied to the first node N1, the magnitude of current flowing through the first pixel transistor TR1 (or the magnitude of current flowing through the light emitting element LD) may be controlled. The first transistor TR1 may be referred to as a driving transistor.

The second pixel transistor TR2 may be configured to switch electrical connection between the second node N2 and a data line DLj. The second pixel transistor TR2 may include a gate electrode connected to the first scan line S1i. The second pixel transistor TR2 may be configured to transmit a voltage (e.g., a data voltage) to be applied to the data line DLj, to the second node N2 in response to a first scan signal GW[i] of a turn-on level. The first scan signal GW[i] may be applied to the first scan line S1i. The second pixel transistor TR2 may be referred to as a switching transistor.

The third pixel transistor TR3 may be configured to switch electrical connection between the first node N1 and the third node N3. The third pixel transistor TR3 may include a gate electrode connected to the fourth scan line S4i. The third pixel transistor TR3 may switch the electrical connection between the first node N1 and the third node N3 in response to a fourth scan signal CG[i]. The fourth scan signal GC[i] may be applied to the fourth scan line S4i. When the third pixel transistor TR3 is turned on, the first pixel transistor TR1 may be operated in the same manner as that of a diode. The third pixel transistor TR3 may be referred to as a compensation transistor.

The fourth pixel transistor TR4 may be configured to switch electrical connection between the first node N1 and a second power line PL2. The fourth pixel transistor TR4 may include a gate electrode connected to the second scan line S2i. The fourth pixel transistor TR4 may switch the electrical connection between the first node N1 and the second power line PL2 in response to a second scan signal GI[i]. The second scan signal GI[i] may be applied to the second scan line S2i. A first initialization voltage Vint1 may be applied to the second power line PL2. When the fourth pixel transistor TR4 is turned on, the voltage of the first node N1 may be initialized to a first initialization voltage Vint1. The fourth pixel transistor TR4 may be referred to as “first initialization transistor”.

The fifth pixel transistor TR5 may be configured to switch electrical connection between the second node N2 and a first power line PL1. The fifth pixel transistor TR5 may include a gate electrode connected to the emission control line EMLi. The fifth pixel transistor TR5 may switch electrical connection between the second node N2 and the first power line PL1 in response to an emission control signal EM[i]. When the fifth pixel transistor TR5 is turned on, a first power voltage VDD may be applied to the second node N2. The fifth pixel transistor TR5 may be referred to as “first emission control transistor”.

The sixth pixel transistor TR6 may be configured to switch electrical connection between the third node N3 and a fourth node N4. The sixth pixel transistor TR6 may include a gate electrode connected to the emission control line EMLi. The sixth pixel transistor TR6 may switch electrical connection between the third node N2 and the fourth node N4 in response to an emission control signal EM[i]. Referring to FIG. 6, the sixth pixel transistor TR6 and the fifth pixel transistor TR5 may be electrically connected to a same emission control line EMLi. The sixth pixel transistor TR6 may be referred to as “second emission control transistor”.

The seventh pixel transistor TR7 may be configured to switch electrical connection between the fourth node N4 and a third power line PL3. The seventh pixel transistor TR7 may include a gate electrode connected to the third scan line S3i. The seventh pixel transistor TR7 may switch the electrical connection between the fourth node N4 and the third power line PL3 in response to a third scan signal GB[i]. When the seventh pixel transistor TR7 is turned on, the voltage of the fourth node N4 may be initialized to a second initialization voltage Vint2. The seventh pixel transistor TR7 may be referred to as “second initialization transistor”.

The capacitor Cst may be configured to maintain the voltage of the first node N1. The capacitor Cst may supply a voltage to the first node N1 during one frame period. The capacitor Cst may include a first side electrode electrically connected to the first node N1, and a second side electrode electrically connected to a power line (e.g., the first power line PL1). A data voltage may be applied to the first side electrode of the capacitor Cst. The capacitor Cst may supply a voltage to the first node N1 during one frame period. The capacitor Cst may be referred to as a storage capacitor.

Each of the first to seventh pixel transistors TR1 to TR7 may be an n-type transistor or a p-type transistor.

In the n-type transistor, a turn-on level voltage may be a high logic level voltage, and a turn-off level voltage may be a low logic level voltage. In the p-type transistor, a turn-on level voltage may be a low logic level voltage, and a turn-off level voltage may be a high logic level voltage.

Referring to FIG. 6, an embodiment where the third pixel transistor TR3 and the fourth pixel transistor TR4 among the first to seventh pixel transistor TR1 to TR7 are implemented using n-type transistors, and the other pixel transistors are implemented using p-type transistors is illustrated. However, the embodiments of the disclosure are not limited to the aforementioned example.

One or more transistors of the first to seventh pixel transistors TR1 to TR7 may include an oxide semiconductor (or an oxide semiconductor layer). One or more transistors of the first to seventh pixel transistors TR1 to TR7 may include a silicon semiconductor, e.g., an amorphous silicon (a-Si) semiconductor or a low temperature polycrystalline silicon (LTPS) semiconductor. In an embodiment, for example, each of the third pixel transistor TR3 and the fourth pixel transistor TR4 may include an oxide semiconductor, but embodiments of the disclosure are not limited thereto.

The light emitting element LD may be connected between the fourth node N4 and a sixth power line EP. The fourth node N4 may be electrically connected to an anode electrode of the light emitting element LD. The sixth power line EP may be electrically connected to a cathode electrode of the light emitting element LD. A second power voltage VSS may be applied to the sixth power line EP.

The light emitting element LD may include an emission layer. Depending on the kind of the emission layer, the light emitting element LD may be implemented as an organic light emitting element including an organic emission layer, an inorganic light emitting element including an inorganic emission layer, a quantum dot light emitting element including a quantum dot (e.g., a nanorod), or the like.

In an embodiment, the single pixel driving circuit PXC may be connected to two or more light emitting elements LD. In such an embodiment, the two or more light emitting elements LD may be connected in series and/or parallel to each other.

In an embodiment, the photo sensor driving circuit PSC may include first to third sensor transistors M1, M2, and M3a.

The first sensor transistor M1 may be configured to switch electrical connection between a fifth power line PL5 and the second sensor transistor M2. The first sensor transistor M1 may include a gate electrode connected to a fifth node N5. The first sensor transistor M1 may switch electrical connection between the fifth power line PL5 and the second sensor transistor M2 depending on the voltage level of the fifth node N5. The fourth power voltage VCOM may be applied to the fifth power supply line PL5.

The second sensor transistor M2 may be configured to switch electrical connection between the first sensor transistor M1 and the sensing line RXk. The second sensor transistor M2 may include a gate electrode connected to the first scan line S1i. The second sensor transistor M2 may electrically connect the first sensor transistor M1 and the sensing line RXk to each other in response to a scan signal (e.g., a first scan signal GW[i]). The second sensor transistor M2 may include a gate electrode electrically connected to the first scan line S1i.

The third sensor transistor M3a may be configured to switch electrical connection between the fourth power line PL4 and the fifth node N5. The third sensor transistor M3a may include a gate electrode electrically connected to the reset control line RSTL. The third sensor transistor M3a may be configured to switch electrical connection between the fourth power line PL4 and the fifth node N5 in response to a reset signal RST inputted to the reset control line RSTL. The third sensor transistor M3a may include a gate electrode connected to the reset control lien RSTL. When the third sensor transistor M3a is turned on, the voltage of the fifth node N5 may be initialized to the third power voltage VRST. Accordingly, the third power voltage VRST may be applied to the light receiving element LRD. The third power voltage VRST may be a turn-off level voltage (e.g., a high logic level voltage) of the first sensor transistor M1. The third power voltage VRST may be referred to as a reset voltage.

In an embodiment, each of the first to third sensor transistors M1, M2, and M3a may be implemented using a p-type transistor or an n-type transistor. Each of the first to third sensor transistors M1, M2, and M3a may include one of an amorphous silicon semiconductor, a low temperature poly silicon semiconductor, and an oxide semiconductor.

Referring to FIG. 6, an embodiment where the third sensor transistor M3a is implemented using an n-type transistor, and each of the first and second sensor transistors M1 and M2 is implemented using a p-type transistor is illustrated. However, the embodiments of the disclosure are not limited to the aforementioned example.

The light receiving element LRD may electrically connect the fifth node N5 and the sixth power line EP to each other in response to light irradiated thereonto. In an embodiment, for example, the light receiving element LRD may be implemented using a photo diode.

A process in which current flows through the sensing line RXk in accordance with embodiments of the disclosure will hereinafter be described.

In embodiments of the disclosure, when light is radiated onto the light receiving element LRD, current may flow through the light receiving element LRD. When current flows through the light receiving element LRD, the voltage of the fifth node N5 may gradually decrease. When the voltage of the fifth node N5 gradually decreases and becomes less than the threshold voltage of the first sensor transistor M1, the first sensor transistor M1 may be turned on. When a first scan signal GW[i] of a turn-on level is applied to the second sensor transistor M2, the second sensor transistor M2 may be turned on. Thereby, when the first sensor transistors M1 and M2 are turned on, a current path extending from the fifth power line PL5 to the sensing line RXk may be formed. The quantity of light that is incident on the light receiving element LRD may be calculated by integrating current flowing through the sensing line RXk (or by sensing a voltage applied thereto).

In embodiments of the disclosure, the quantity of reflective light that is reflected by an object adjacent to the photo sensor PHS may be measured by using the photo sensor PHS.

In an embodiment, the electronic device 100 (refer to FIG. 1) may acquire (or generate) a pattern of an object (e.g., a pattern of a fingerprint or the like) adjacent to the photo sensor PHS by sensing the photo sensor PHS. Hence, the electronic device 100 in accordance with embodiments of the disclosure may provide a biometric authentication function (e.g., a fingerprint authentication function).

In an embodiment, the electronic device 100 (refer to FIG. 1) may provide a function of detecting an ambient illumination of the electronic device 100 by sensing the photo sensor PHS, and adaptively adjusting the luminance of the electronic device 100 based on the detected ambient illumination.

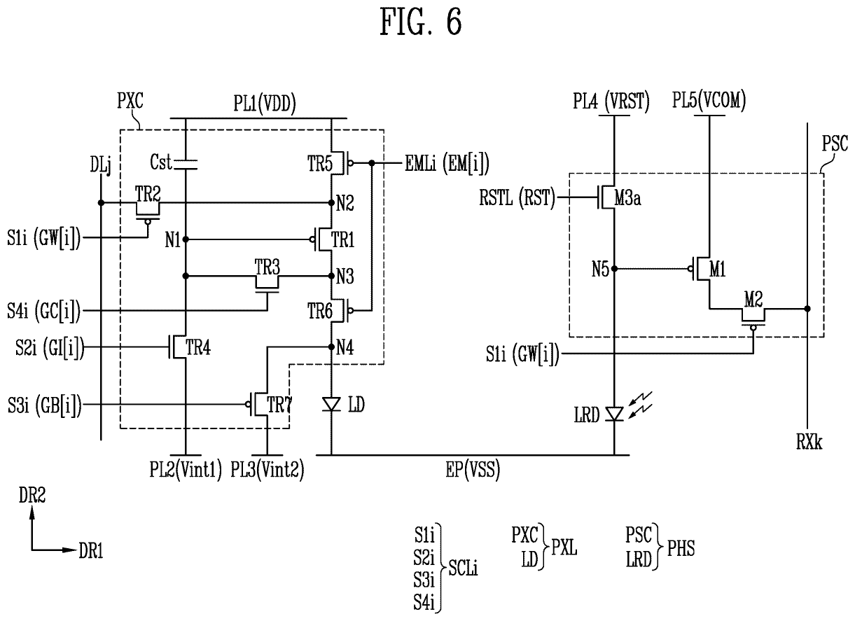

FIG. 7 is a diagram illustrating image display areas IR1 and IR2 and a black area BR at a first timing in the display panel 210 in accordance with embodiments of the disclosure.

Referring to FIG. 7, in an embodiment, the display panel 210 may include the first image display area IR1, the second image display area IR2, and the black area BR at the first timing. The black area BR may be positioned between the first image display area IR1 and the second image display area IR2.

The first image display area IR1 may correspond to an area where first to x-th emission control lines EML1 to EMLx (where x is an integer equal to or greater than 1 and less than m) are positioned. First to x-th emission control signals EM[1] to EM[x] may be supplied to the first to x-th emission control lines EML1 to EMLx, respectively. At the first timing, the first to x-th emission control signals EM[1] to EM[x] may have a turn-on level.

The black area BR may correspond to an area where (x+1)-th to y-th emission control lines EMLx+1 to EMLy (where y is an integer greater than x and less than m) are positioned. (x+1)-th to y-th emission control signals EM[x+1] to EM[y] may be supplied to the (x+1)-th to y-th emission control lines EMLx+1 to EMLy, respectively. At the first timing, the (x+1)-th to y-th emission control signals EM[x+1] to EM[y] may have a turn-off level.

The second image display area IR2 may correspond to an area where (y+1)-th to m-th emission control lines EMLy+1 to EMLm are positioned. (y+1)-th to m-th emission control signals EM[y+1] to EM[m] may be supplied to the (y+1)-th to m-th emission control lines EMLy+1 to EMLm, respectively. At the first timing, the y+1-th to m-th emission control signals EM[y+1] to EM[m] may have a turn-on level.

Referring to FIG. 7, the second display area AA2 may be positioned in the second image display area IR2. At the first timing, an image may be displayed in the second display area AA2. A reset control signal RST may be supplied to the second display area AA2 through the reset control line RSTL. At the first timing, the reset control signal RST supplied to the second display area AA2 may have a turn-off level.

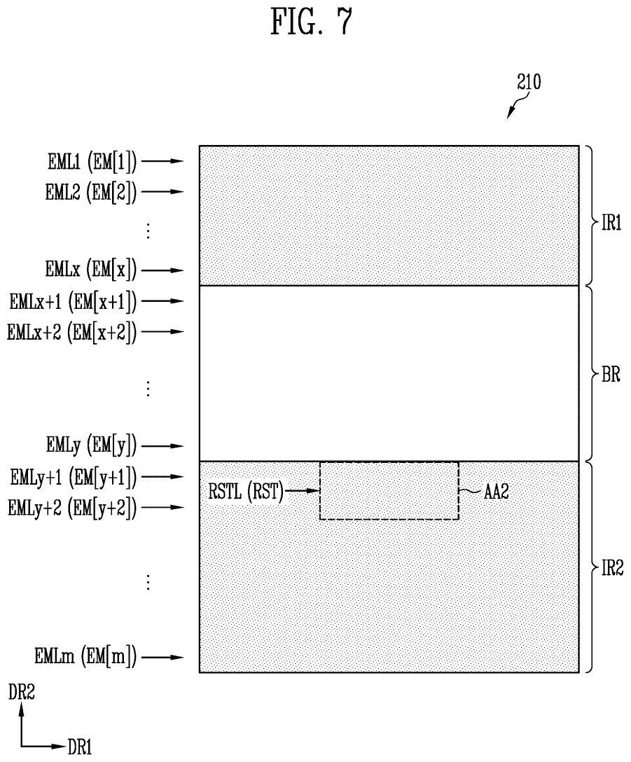

FIG. 8 is a diagram illustrating the image display areas IR1 and IR2 and the black area BR at a second timing in the display panel 210 in accordance with embodiments of the disclosure.

The second timing of FIG. 8 may be a timing after the first timing described with reference to FIG. 7, and may be any timing within the same frame period as the first timing of FIG. 7.

The first image display area IR1 may correspond to an area where first to p-th emission control lines EML1 to EMLp (where p is an integer equal to or greater than 1 and less than m) are positioned. First to p-th emission control signals EM[1] to EM[p] may be supplied to the first to p-th emission control lines EML1 to EMLp, respectively. At the second timing, the first to p-th emission control signals EM[1] to EM[p] may have a turn-on level.

The black area BR may correspond to an area where the p+1-th to q-

th emission control lines EMLp+1 to EMLq (where q is an integer greater than p and less than m) are positioned. (p+1)-th to q-th emission control signals EM[p+1] to EM[q] may be supplied to the (p+1)-th to q-th emission control lines EMLp+1 to EMLq, respectively. At the second timing, the (p+1)-th to q-th emission control signals EM[p+1] to EM[q] may have a turn-off level.

The second image display area IR2 may correspond to an area where (q+1)-th to m-th emission control lines EMLq+1 to EMLm are positioned. (q+1)-th to m-th emission control signals EM[q+1] to EM[m] may be supplied to the (q+1)-th to m-th emission control lines EMLq+1 to EMLm, respectively. At the second timing, the (q+1)-th to m-th emission control signals EM[q+1] to EM[m] may have a turn-on level.

Referring to FIG. 8, the second display area AA2 may be positioned in the black area BR. At the second timing, a black image may be displayed in the second display area AA2. A reset control signal RST may be supplied to the second display area AA2 through the reset control line RSTL. At the second timing, the reset control signal RST supplied to the second display area AA2 may have a turn-off level. For example, at the second timing, the reset control signal RST supplied to the second display area AA2 may make a transition from a turn-on level to a turn-off level, or may make a transition from a turn-off level to a turn-on level.

Referring to FIGS. 7 and 8, at the first timing of FIG. 7, light (e.g., internal light) may be introduced into the second display area AA2 from other pixels positioned in the second image display area IR2. On the other hand, at the second timing of FIG. 8, internal light may not be introduced into the second display area AA2 from other pixels positioned in the black area BR. Accordingly, the photo sensor positioned in the second display area AA2 may be sensed with reduced (e.g., removed) influence from internal light.

The size of the black area BR in FIG. 7 is substantially the same as that of the black area BR in FIG. 8. For example, a value of y-x in FIG. 7 may be the same as a value of q-p in FIG. 8.

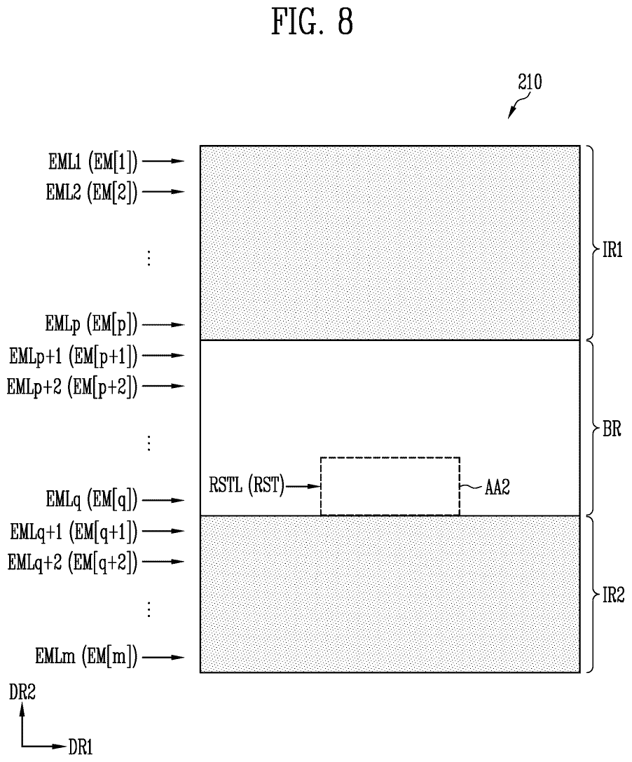

FIG. 9 is a timing diagram illustrating an emission control signal and a reset control signal in accordance with embodiments of the disclosure.

Referring to FIG. 9, (p+1)-th to 1-th emission control signals EM[p+1] to EM[q] of a turn-off level OFF may be sequentially supplied.

The (p+1)-th emission control signal EM[p+1] may make a transition from a turn-on level ON to the turn-off level OFF at a first start timing ST1. The (p+1)-th emission control signal EM[p+1] may make a transition from the turn-off level OFF to the turn-on level ON at a first end timing ET1.

The q-th emission control signal EM[q] may make a transition from the turn-on level ON to the turn-off level OFF at a second start timing ST2. The q-th emission control signal EM[q] may make a transition from the turn-off level OFF to the turn-on level ON at a second end timing ET2.

The reset control signal RST may make a transition from the turn-off level OFF to the turn-on level ON at a reset start timing RS. The reset control signal RST may make a transition from the turn-on level ON to the turn-off level OFF at a reset end timing RE. A period between the reset start timing RS and the reset end timing RE may correspond to a reset period RP.

The reset start timing RS may occur later than the second start timing ST2. The reset end timing RE may occur earlier than the first end timing ET1.

Accordingly, during at least some periods within a period in which the (p+1)-th to q-th emission control signals EM[p+1] to EM[q] have the turn-off level OFF, the reset control signal RST may have the turn-on level ON. Referring further to FIG. 8 described above, during a period in which a reduced amount of internal light is introduced into the second display area AA2, a reset control signal RST of the turn-on level ON may be supplied to the second display area AA2. Accordingly, sensing of the photo sensor may be performed with reduced influence from the internal light.

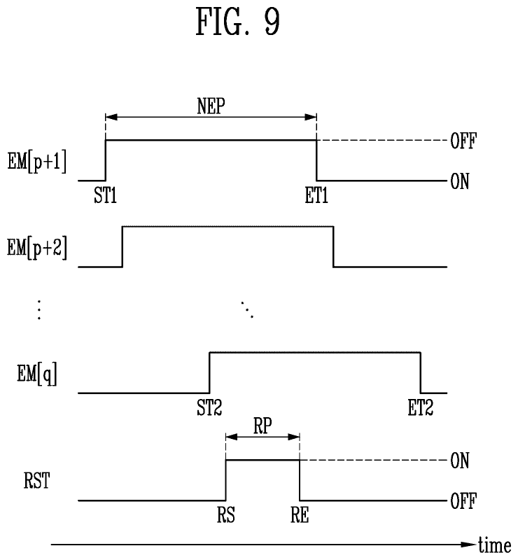

FIG. 10 illustrates an equivalent circuit diagram of the readout circuit 350 in accordance with embodiments of the disclosure.

Referring to FIG. 10, the readout circuit 350 in accordance with embodiments of the disclosure may include an integrator 1010, and a sample-and-hold circuit 1020 (also referred to as “correlated double sampling circuit”).

The integrator 1010 may include an operational amplifier OP-AMP, a feedback capacitor Cfb, and a first switching element SW1. The first switching element SW1 may be controlled based on operation timing by an integrator reset signal IRST.

The operational amplifier OP-AMP may include a first input terminal, e.g., (−) input terminal, a second input terminal, e.g., (+) input terminal, and an output terminal.

The first input terminal of the operational amplifier OP-AMP may be electrically connected to at least one of the plurality of sensing lines RX1 to RXo (refer to FIG. 3). In such an embodiment, a multiplexer may be further disposed between the first input terminal of the operational amplifier OP-AMP and the plurality of sensing lines. A voltage VCrx from a first side electrode of the capacitor Crx corresponding to a voltage of the sensing line on the equivalent circuit may be applied to the first input terminal of the operational amplifier OP-AMP. A ground voltage GND may be applied to a second side electrode of the capacitor Crx on the equivalent circuit.

The second input terminal of the operational amplifier OP-AMP may be electrically connected to the power line PL to which a constant voltage is applied.

In an embodiment, the power line PL may be grounded. However, embodiments of the disclosure are not limited to the foregoing example.

The feedback capacitor Cfb may include a first side electrode electrically connected to the first input terminal of the operational amplifier OP-AMP, and a second side electrode electrically connected to the output terminal of the operational amplifier OP-AMP.

The first switching element SW1 may be configured to switch electrical connection between the first input terminal and the output terminal of the operational amplifier OP-AMP. When the first switching element SW1 is turned on, charges stored in the feedback capacitor Cfb may be discharged, and the feedback capacitor Cfb may be reset.

The sample-and-hold circuit 1020 may include a second switching element SW2, a third switching element SW3, a first sampling capacitor Cs1, a second sampling capacitor Cs2, a differential amplifier DA, a fourth switching element SW4, or the like. The sample-and-hold circuit 1020 may include a sixth node N6 electrically connected to an output terminal of the integrator 1010 (e.g., the output terminal of the operational amplifier OP-AMP). In embodiments of the disclosure, the sample-and-hold circuit 1020 may be configured to store a value acquired by sensing the photo sensor and output an analog voltage acquired by removing (reducing) a noise component from the sensed value.

The second switching element SW2 may be configured to switch electrical connection between the sixth node N6 and the first sampling capacitor Cs1. The second switching element SW2 may be controlled in operation timing in response to a second sampling signal SHR.

The first sampling capacitor Cs1 may be configured to store a value corresponding to the noise component. The noise component may include, for example, a noise component which is basically present in the sensing line (e.g., RXk; refer to FIG. 6). In an embodiment, the first sampling capacitor Cs1 may include a first side electrode electrically connected to the second switching element SW2, and a second side electrode to which the ground voltage GND is applied.

The third switching element SW3 may be configured to switch electrical connection between the sixth node N6 and the second sampling capacitor Cs2. The third switching element SW3 may be controlled based on operation timing in response to a first sampling signal SHS.

The second sampling capacitor Cs2 may be configured to store a value acquired by sensing the photo sensor including a noise component. The second sampling capacitor Cs2 may include a first side electrode electrically connected to the third switching element SW3, and a second side electrode to which the ground voltage GND is applied.

The differential amplifier DA may include a first input terminal, e.g., (−) input terminal, a second input terminal, e.g., (+) input terminal, and an output terminal. The differential amplifier DA may be configured to amplify and output a signal corresponding to a difference between a signal inputted to the second input terminal and a signal inputted to the first input terminal.

The first input terminal of the differential amplifier DA may be configured to receive a voltage applied from the first sampling capacitor Cs1. A buffer BUF may be further disposed between the first input terminal of the differential amplifier DA and the first sampling capacitor Cs1.

The second input terminal of the differential amplifier DA may be configured to receive a voltage applied from the second sampling capacitor Cs2. A buffer BUF may be further disposed between the second input terminal of the differential amplifier DA and the second sampling capacitor Cs2.

The fourth switching element SW4 may be configured to switch electrical connection between the output terminal of the differential amplifier DA and an input terminal OUT of the ADC 352. When the fourth switching element SW4 is turned on, a sensing voltage VSEN corresponding to the light receiving quantity of the photo sensor may be inputted to the ADC 352.

The second switching element SW2 and the third switching element SW3 each may correspond to a switching element for sampling a signal. The fourth switching element SW4 may correspond to a switching element for holding a signal.

The ADC 352 may convert the inputted sensing voltage VSEN to a digital value, and output the converted digital value DSEN.

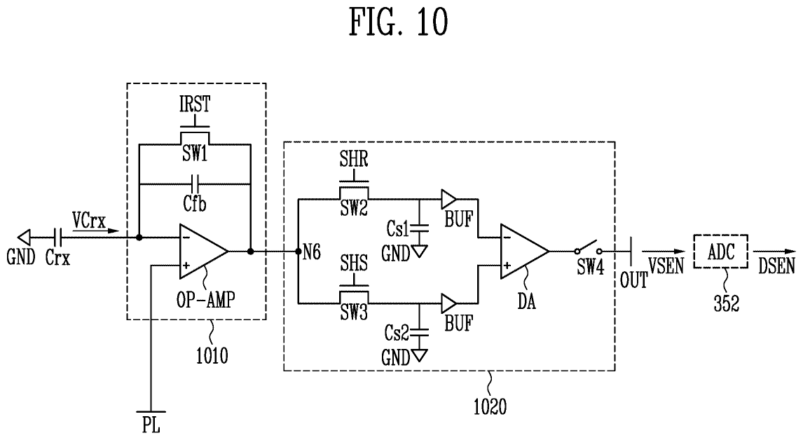

FIG. 11 is a timing diagram of a first scan signal, an integrator reset signal, and sampling signals in accordance with embodiments of the disclosure.

In FIG. 11, signal timing of i-th to (i+4)-th first scan signals GW[i], GW[i+1], GW[i+2], GW[i+3], and GW[i+4] are illustrated. The i-th to (i+4)-th first scan signals GW[i], GW[i+1], GW[i+2], GW[i+3], and GW[i+4] of a turn-on level ON may be sequentially inputted.

A distance between a timing at which the i-th first scan signal GW[i] of the turn-on level ON is inputted and a timing at which the (i+1)-th first scan signal GW[i+1] of the turn-on level ON may correspond to one horizontal period 1H.

A period between timings at which first sampling signals SHS of a turn-on level ON are inputted may correspond to the sensing period SNP. The length of the sensing period SNP may be equal to or greater than two horizontal periods. In an embodiment, the length of the sensing period SNP may be four horizontal periods. However, embodiments of the disclosure are not limited to the foregoing example.

At least one photo sensor may be sensed during the sensing period SNP.

The length of the sensing period SNP may correspond to a sensing cycle on which the photo sensors are sensed.

During at least some periods of a period in which the first sampling signal SHS of the turn-on level ON is inputted, the first scan signal of the turn-on level ON may be inputted. For example, during at least some periods of the period in which the first sampling signal SHS of the turn-on level ON is inputted, the i-th first scan signal GW[i] or the (i+4)-th first scan signal GW[i+4] of the turn-on level ON may be inputted.

The length of a period between timings at which second sampling signals SHR of a turn-on level ON are sequentially inputted may be substantially the same as that of the sensing period SNP. The length of a period between timings at which integrator reset signals IRST of a turn-on level ON are sequentially inputted may be substantially the same as that of the sensing period SNP.

The integrator reset signal IRST of the turn-on level ON, the second sampling signal SHR of the turn-on level ON, and the first sampling signal SHS of the turn-on level ON may be sequentially inputted.

In an embodiment, the length of the period in which the first sampling signal SHS of the turn-on level ON is applied may be greater than that of the period in which the second sampling signal SHR of the turn-on level ON is inputted. However, embodiments of the disclosure are not limited to the foregoing example.

In an embodiment show in FIGS. 4, 6, and 10, the photo sensor PHS may be sensed on a four-pixel-row basis.

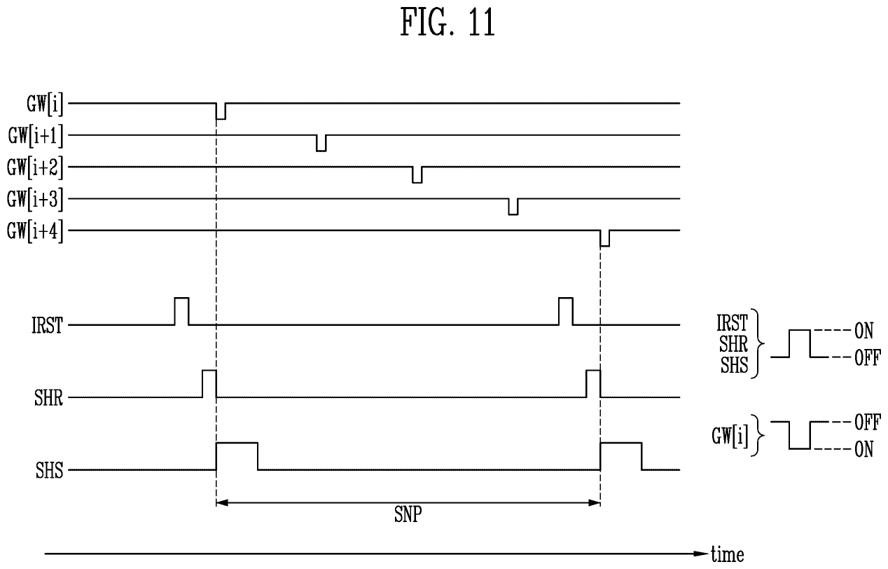

FIG. 12 is a timing diagram illustrating lengths of a reset period RP and a sensing period SNP in accordance with embodiments of the disclosure.

Referring to FIG. 12, the length of the reset period RP may be greater than that of the sensing period SNP. In an embodiment, the length of the reset period RP may be equal to or greater than twice the length of the sensing period SNP.

Accordingly, the sensing period SNP corresponding to the cycle of sensing the photo sensors may always be included in the reset period RP. In such an embodiment, the photo sensors may be sensed with reduced (e.g., minimized) influence from internal light, such that the accuracy of sensing the photo sensor may be further enhanced.

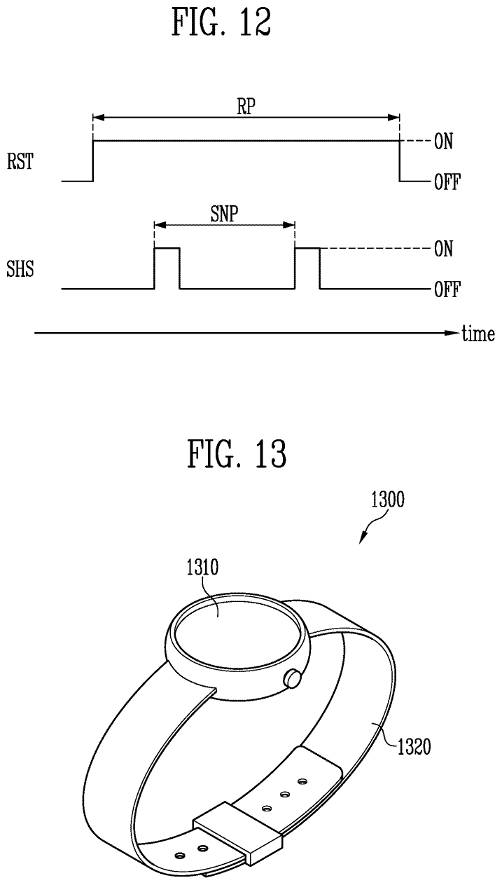

FIG. 13 is a perspective diagram illustrating an application example of the electronic device 100 of FIG. 1.

Referring to FIG. 13, an embodiment of the electronic device 100 of FIG. 1 may be applied to a smart watch 1300 including a display component 1310 and a strap 1320. The smart watch 1300 may be a wearable electronic device. In an embodiment, for example, the smart watch 1300 may have a structure in which the strap 1320 may be mounted on the wrist of the user. The electronic device 100 or the display device 110 (refer to FIG. 1) may be applied to the display component 1310, so that image data including time information may be provided to the user.

In a display device and a method of driving the display device in accordance with embodiments of the disclosure, accuracy of sensing a photo sensor may be enhanced by reducing influence of internal light.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a substrate on which a reset control line, a sensing line, and an emission control line are disposed;
an emission driving circuit which supplies an emission control signal to the emission control line;
a reset circuit which supplies a reset control signal to the reset control line;
a pixel disposed on the substrate, wherein the pixels includes a pixel circuit connected to the emission control line, and a light emitting element which receives a current from the pixel circuit in response to the emission control signal of a turn-on level;
a photo sensor disposed on the substrate, wherein the photo sensor includes a photo sensor driving circuit connected to the reset control line and the sensing line, and a light receiving element which receives a reset voltage in response to the reset control signal of a turn-on level; and
a readout circuit which differentially amplifies and outputs voltages of the sensing line respectively sensed in response to a first sampling signal and a second sampling signal,
wherein a length of a reset period, during which the reset control signal of the turn-on level is inputted, is equal to or greater than twice a length of a sensing period which is a cycle on which the first sampling signal of a turn-on level is sequentially inputted.

2. The display device according to claim 1, wherein the pixel circuit comprises:
a driving transistor connected between a second node and a third node, and including a gate electrode connected to a first node;
a first emission control transistor connected between the second node and a first power line, and including a gate electrode connected to the emission control line; and
a second emission control transistor connected between the third node and the light emitting element, and including a gate electrode connected to the emission control line.

3. The display device according to claim 2,
wherein the pixel circuit further comprises a switching transistor connected between a data line and the second node, and including a gate electrode connected to a first scan line,
wherein the photo sensor driving circuit comprises:
a first sensor transistor connected to a fifth power line to which a power voltage is applied, and including a gate electrode connected to the light receiving element;
a second sensor transistor connected between the first sensor transistor and the sensing line, and including a gate electrode connected to the first scan line; and
a third sensor transistor connected between the light receiving element and a fourth power line to which the reset voltage is applied, and including a gate electrode connected to the reset control line.

4. The display device according to claim 3, wherein the pixel circuit further comprises:
a compensation transistor connected between the first node and the third node, and including a gate electrode connected to a fourth scan line;
a first initialization transistor connected between the first node and a second power line, and including a gate electrode connected to a second scan line;
a second initialization transistor connected between the light emitting element and a third power line, and including a gate electrode connected to a third scan line; and
a storage capacitor including a first side electrode connected to the first node, and a second side electrode connected to the first power line.

5. The display device according to claim 1, wherein a length of a period in which the emission driving circuit supplies the emission control signal of the turn-on level to the emission control line is greater than the length of the reset period.

6. The display device according to claim 1,
wherein the readout circuit includes an integrator and a sample-and-hold circuit, and
wherein the integrator comprises:
an operational amplifier including a first input terminal connected to the sensing line, and a second input terminal to which a constant voltage is applied;
a feedback capacitor connected between the first input terminal of the operational amplifier and an output terminal of the operational amplifier; and
a first switching element connected between the first input terminal of the operational amplifier and the output terminal of the operational amplifier, wherein the sample-and-hold circuit comprises:
a second switching element which switches electrical connection between the output terminal of the operational amplifier and a first sampling capacitor in response to the second sampling signal;
a third switching element which switches electrical connection between the output terminal of the operational amplifier and a second sampling capacitor in response to the first sampling signal; and
a differential amplifier including a first input terminal which receives a voltage corresponding to a voltage stored in the first sampling capacitor, and a second input terminal which receives a voltage corresponding to a voltage stored in the second sampling capacitor.

7. The display device according to claim 6,
wherein the first switching element electrically connects the first input terminal of the operational amplifier to the output terminal of the operational amplifier in response to an integrator reset signal, and
wherein the integrator reset signal of a turn-on level, the second sampling signal of a turn-on level, and the first sampling signal of a turn-on level are sequentially inputted.

8. The display device according to claim 6, wherein the readout circuit further comprises:
a fourth switching element connected to the output terminal of the operational amplifier; and
an analog-to-digital converter which converts a sensing voltage inputted thereto through the fourth switching element to a digital value and outputs the digital value.

9. The display device according to claim 1, wherein the length of the sensing period is equal to or greater than two horizontal periods.

10. The display device according to claim 1,
wherein the pixel and the photo sensor are positioned in an area on the substrate, and
wherein the reset control signal is inputted within a period during which the emission control signal of a turn-off level is supplied to the pixel.

11. The display device according to claim 1, wherein a length of a period during which the first sampling signal is at a turn-on level is greater than a length of a period during which the second sampling signal is at a turn-on level.

12. A display device, comprising:
a display panel in which a plurality of pixel rows are disposed;
an emission driving circuit which supplies an emission control signal of a turn-on level to pixels positioned in a first image display area, supplies the emission control signal of the turn-on level to pixels positioned in a second image display area, and supplies the emission control signal of a turn-off level to pixel rows positioned in a black area located between the first image display area and the second image display area;
a reset circuit which supplies a reset control signal of a turn-on level to a plurality of photo sensors positioned in the black area during a reset period; and
a readout circuit which senses the plurality of photo sensors based on a cycle corresponding to a sensing period,
wherein a length of a reset period during which the reset control signal of the turn-on level is inputted is equal to or greater than twice a length of the sensing period.

13. The display device according to claim 12,
wherein at least one of the plurality of pixel rows includes a pixel and the photo sensor,
wherein the pixel comprises:
a pixel circuit which receives the emission control signal; and
a light emitting element which receives a current from the pixel circuit in response to the emission control signal of the turn-on level,
wherein the photo sensor comprises:
a photo sensor driving circuit connected to a sensing line, wherein the photo sensor driving circuit receives the reset control signal; and
a photo sensor which receives a reset voltage in response to the reset control signal of the turn-on level.

14. The display device according to claim 13, wherein the readout circuit is connected to the sensing line.

15. The display device according to claim 13,
wherein the readout circuit includes an integrator and a sample-and-hold circuit, and
wherein the integrator comprises:
an operational amplifier including a first input terminal connected to the sensing line, and a second input terminal to which a constant voltage is applied;
a feedback capacitor connected between the first input terminal of the operational amplifier and an output terminal of the operational amplifier; and
a first switching element connected between the first input terminal of the operational amplifier and the output terminal of the operational amplifier,
wherein the sample-and-hold circuit comprises:
a second switching element which switches electrical connection between the output terminal of the operational amplifier and a first sampling capacitor in response to a second sampling signal;
a third switching element which switches electrical connection between the output terminal of the operational amplifier and a second sampling capacitor in response to a first sampling signal; and
a differential amplifier including a first input terminal which receives a voltage corresponding to a voltage stored in the first sampling capacitor, and a second input terminal which receives a voltage corresponding to a voltage stored in the second sampling capacitor.

16. The display device according to claim 15, wherein the sensing period corresponds to a period between timings at which the first sampling signal of a turn-on level is sequentially inputted.

17. The display device according to claim 16, wherein the length of the sensing period is equal to or greater than two horizontal periods.

18. A method of driving a display device, the method comprising:
supplying an emission control signal of a turn-on level to a plurality of pixel rows positioned in a first image display area of a display panel;
supplying the emission control signal of the turn-on level to a plurality of pixel rows positioned in a second image display area of the display panel;
supplying the emission control signal of a turn-off level to a plurality of pixel rows positioned in a black area between the first image display area and the second image display area of the display panel;
supplying a reset control signal of a turn-on level to a plurality of photo sensors positioned in the black area; and
sensing the plurality of photo sensors based on a cycle corresponding to a sensing period,
wherein a length of a reset period during which the reset control signal of the turn-on level is inputted is equal to or greater than twice a length of the sensing period.

19. The method according to claim 18, wherein the length of the sensing period is equal to or greater than two horizontal periods.

20. The method according to claim 18, wherein the supplying the reset control signal of the turn-on level to the plurality of photo sensors comprises applying a reset voltage to a light receiving element of each of the plurality of photo sensors.
